(19) United States
(12) Patent Application Publication
(10) Pub. No.: US 2024/0250496 A1
(43) Pub. Date: Jul. 25, 2024

(54) METHOD OF MANUFACTURING SEMICONDUCTOR OPTICAL DEVICE

(71) Applicant: Sumitomo Electric Industries, Ltd., Osaka (JP)

(72) Inventor: Takehiko KIKUCHI, Osaka-shi (JP)

(73) Assignee: Sumitomo Electric Industries, Ltd., Osaka (JP)

(21) Appl. No.: 18/402,919

(22) Filed: Jan. 3, 2024

(30) Foreign Application Priority Data
Jan. 23, 2023 (JP) 2023-008060

(51) Int. Cl. H01S 5/02; H01S 5/30; H01S 5/323

(52) U.S. Cl. CPC H01S 5/0207; H01S 5/0203; H01S 5/0218; H01S 5/3013; H01S 5/32316; H01S 5/3235

(57) ABSTRACT

A method of manufacturing a semiconductor optical device is a method of manufacturing a semiconductor optical device including a chip containing a III-V compound semiconductor and a first substrate. The chip includes a second substrate and a semiconductor layer stacked on the second substrate. The method includes forming the chip by cutting the second substrate and the semiconductor layer, bonding the semiconductor layer of the chip to the first substrate, removing the second substrate by etching the chip bonded to the first substrate. A shape of the chip in plan view does not have a side perpendicular to a first direction. In the removing the second substrate, etching proceeds more easily in a second direction crossing the first direction than in the first direction.

### CROSS REFERENCE TO RELATED APPLICATIONS

This application claims priority based on Japanese Patent Application No. 2023-008060 filed on Jan. 23, 2023, and the entire contents of the Japanese patent application are incorporated herein by reference.

### TECHNICAL FIELD

The present disclosure relates to a method of manufacturing a semiconductor optical device.

### BACKGROUND

There is known a technique for bonding a semiconductor device formed of a compound semiconductor and having an optical gain to a substrate such as a silicon on insulator (SOI) substrate (silicon photonics) in which a waveguide is formed (for example, PTL 1). For example, a semiconductor layer is grown on a wafer of the compound semiconductor such as indium phosphide (InP). The semiconductor device is formed by cutting the wafer. The semiconductor device is bonded to the SOI substrate. After the bonding, etching or the like is performed on the semiconductor device.
PTL 1: Japanese Unexamined Patent Application Publication No. 2015-164148

### SUMMARY

A method of manufacturing a semiconductor optical device according to the present disclosure is a method of manufacturing a semiconductor optical device including a chip containing a III-V compound semiconductor and a first substrate. The chip includes a second substrate and a semiconductor layer stacked on the second substrate. The manufacturing method includes forming the chip by cutting the second substrate and the semiconductor layer, bonding the semiconductor layer of the chip to the first substrate, removing the second substrate by etching the chip bonded to the first substrate. A shape of the chip in plan view does not have a side perpendicular to a first direction. In the removing the second substrate, etching proceeds more easily in a second direction crossing the first direction than in the first direction.

### BRIEF DESCRIPTION OF THE DRAWINGS

FIG. 1A is a perspective view illustrating a semiconductor optical device according to a first embodiment.

FIG. 1B is a cross-sectional view taken along line A-A of FIG. 1A.

FIG. 2A is a diagram illustrating a method of manufacturing a semiconductor optical device.

FIG. 2B is a diagram illustrating a method of manufacturing a semiconductor optical device.

FIG. 3A is a diagram illustrating a method of manufacturing a semiconductor optical device.

FIG. 3B is a diagram illustrating a method of manufacturing a semiconductor optical device.

FIG. 4 is a diagram illustrating a method of manufacturing a semiconductor optical device.

FIG. 5A is a diagram illustrating a method of manufacturing a semiconductor optical device.

FIG. 5B is a diagram illustrating a method of manufacturing a semiconductor optical device.

FIG. 6A is a diagram illustrating a method of manufacturing a semiconductor optical device.

FIG. 6B is a diagram illustrating a method of manufacturing a semiconductor optical device.

FIG. 7A is a diagram illustrating a method of manufacturing a semiconductor optical device.

FIG. 7B is a diagram illustrating a method of manufacturing a semiconductor optical device.

FIG. 8A is a plan view illustrating a method of manufacturing a semiconductor optical device according to a comparative example.

FIG. 8B is a cross-sectional view along line D-D of FIG. 8A.

FIG. 9A is a plan view illustrating a method of manufacturing a semiconductor optical device according to a comparative example.

FIG. 9B is a cross-sectional view taken along line D-D of FIG. 9A.

FIG. 10 is a plan view illustrating a method of manufacturing a semiconductor optical device according to a second embodiment.

FIG. 11 is a plan view illustrating a method of manufacturing a semiconductor optical device according to a third embodiment.

### DETAILED DESCRIPTION

In the etching after the bonding, residues may occur due to anisotropy of the etching. The residues become an obstacle to the subsequent processes such as application of a resist. Therefore, it is an object of the present disclosure to provide a method of manufacturing a semiconductor optical device capable of suppressing occurrence of the residues in the etching.

### DESCRIPTION OF EMBODIMENTS OF PRESENT DISCLOSURE

First, the contents of embodiments of the present disclosure will be listed and explained.

(1) An aspect of the present disclosure is a method of manufacturing a semiconductor optical device including a chip containing a III-V compound semiconductor and a first substrate. The chip includes a second substrate and a semiconductor layer stacked on the second substrate. The manufacturing method includes forming the chip by cutting the second substrate and the semiconductor layer, bonding the semiconductor layer of the chip to the first substrate, and removing the second substrate by etching the chip bonded to the first substrate. A shape of the chip in plan view does not have a side perpendicular to a first direction. In the removing the second substrate, etching proceeds more easily in a second direction crossing the first direction than in the first direction. Since the shape of the chip in plan view does not have a side perpendicular to the first direction, a surface with a low etching rate is less likely to be exposed in the etching of the second substrate. The etching of the second substrate proceeds more easily. Occurrence of residues in the etching is suppressed. The influence of the etching residues on the semiconductor optical device is suppressed.

(2) In the above (1), the chip may have a polygonal shape when viewed in plan view and may have a side inclined from a line extending in the second direction. In the etching of the second substrate, the surface with a low etching rate is less likely to be exposed. The etching of the second substrate proceeds more easily. Occurrence of the residues in the etching is suppressed.

(3) In the above (2), the side, which is inclined, includes two sides, and the two sides may form a vertex. The vertex may have an angle of 60° to 120°. The sides become away from lines perpendicular to the first direction. When the etching proceeds to the vertex, the etching proceeds to the semiconductor layer in the thickness direction. Occurrence of the residues is suppressed.

(4) In the above (2) or (3), the chip may have a hexagonal shape when viewed in plan view. Two of six sides of the hexagonal shape may form a vertex. Other two of the six sides may form another vertex. The vertex and the other vertex may face each other in the first direction. In the etching of the second substrate, the surface with a low etching rate is less likely to be exposed. The etching of the second substrate proceeds more easily. Occurrence of the residues in the etching is suppressed. The etching proceeds to one vertex and to another vertex. Occurrence of the residues on both sides of the chip can be suppressed.

(5) In the above (3) or (4), a plurality of the vertices may be aligned in the second direction. At least one of the vertices and at least another one of the vertices may face each other in the first direction. The etching proceeds to the plurality of the vertices. Occurrence of the residues on both sides of the chip can be suppressed.

(6) In any one of (1) to (3), the chip may have a parallelogram shape when viewed in plan view. In the etching of the second substrate, the surface with a low etching rate is less likely to be exposed. The etching of the second substrate proceeds more easily. Occurrence of the residues in the etching is suppressed.

(7) In the above (6), the two inclined sides may form a vertex. The vertex may have an angle of 45° or more and less than 90°. The sides become away from the lines perpendicular to the first direction. When the etching proceeds to the vertex, the etching proceeds to the semiconductor layer in the thickness direction. Occurrence of the residues is suppressed.

(8) In any one of the above (1) to (7), in the forming the chip, the second substrate and the semiconductor layer may be cut by using an optical method.

(9) In any one of the above (1) to (8), the second substrate may contain indium phosphide. The semiconductor layer may contain indium gallium arsenide. In the removing the second substrate, the second substrate may be removed by wet etching using an etchant containing hydrochloric acid.

A high etching selectivity can be obtained between the second substrate and the semiconductor layer. The second substrate is removed by the etching. The etching stops at the semiconductor layer.

(10) In any one of the above (1) to (9), the semiconductor layer may include a first semiconductor layer and a second semiconductor layer. In the second substrate, the first semiconductor layer, and the second semiconductor layer are sequentially stacked on top of one another. In the bonding, the second semiconductor layer is bonded to the first substrate. The manufacturing method may further include removing the first semiconductor layer after the removing the second substrate, and etching the second semiconductor layer. The influence of the residues on the process of the second semiconductor layer is suppressed.

### DETAILS OF EMBODIMENTS OF PRESENT DISCLOSURE

Specific examples of a method of manufacturing a semiconductor optical device according to the embodiments of the present disclosure will be described below with reference to the drawings. The present disclosure is not limited to these examples, and is defined by the scope of the claims, and is intended to include all modifications within the meaning and scope equivalent to the scope of the claims.

### First Embodiment

### (Semiconductor Optical Device)

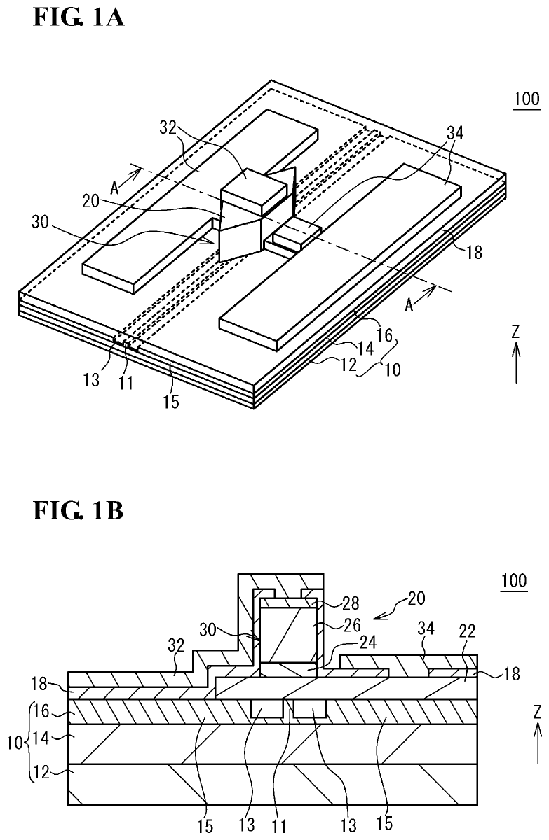

FIG. 1A is a perspective view illustrating a semiconductor optical device 100 according to a first embodiment. FIG. 1B is a cross-sectional view taken along line A-A of FIG. 1A. As illustrated in FIGS. 1A and 1B, semiconductor optical device 100 is a hybrid laser device including a substrate 10 (first substrate) and a semiconductor device 20. Semiconductor device 20 is a device containing a III-V compound semiconductor layer. Semiconductor device 20 has, for example, an optical gain and generates light. In another example, semiconductor device 20 is light sensitive and absorbs light to generate a photocurrent. Semiconductor device 20 may modulate light by changing a refractive index according to a voltage. Substrate 10 propagates light. A Z-axis direction is a normal direction of a top surface of substrate 10.

As illustrated in FIG. 1B, substrate 10 is an SOI substrate including a substrate 12, a box layer 14, and a silicon (Si) layer 16, that are sequentially stacked in the Z-axis direction. Substrate 12 is formed of, for example, Si. Box layer 14 is formed of, for example, silicon oxide (SiO₂). A thickness of box layer 14 is, for example, 3 μm. A thickness of Si layer 16 is, for example, 220 nm. The top surface of substrate 10 is covered by an electrically insulating film 18. Electrically insulating film 18 is formed of, for example, SiO₂ having a thickness of 1 μm. A refractive index of Si layer 16 is 3.45. A refractive index of each of box layer 14 and electrically insulating film 18 is 1.45, which is lower than the refractive index of Si layer 16.

Si layer 16 of substrate 10 has a waveguide 11, two recesses 13, and two terraces 15. Waveguide 11 and recess 13 extend in the same direction. Two recesses 13 are located on both sides of waveguide 11 and extend in the same direction as waveguide 11. Terrace 15 is a plane of Si layer 16 and is located opposite to waveguide 11 with respect to recess 13. Although a bottom surface of recess 13 is Si layer 16 in FIG. 1B, the bottom surface may be box layer 14. Si layer 16 may be provided with optical components such as a ring resonator and a loop mirror. For example, a ring resonator is formed by bending waveguide 11 into a ring shape.

As illustrated in FIG. 1B, semiconductor device 20 is bonded to a top surface of Si layer 16 on waveguide 11 and recess 13. Semiconductor device 20 includes a cladding layer 22, an active layer 24, a cladding layer 26, and a contact layer 28. Cladding layer 22 to contact layer 28 are sequentially stacked upward from the top surface of substrate 10.

Cladding layer 22 is formed of, for example, n-type indium phosphide (n-InP) having a thickness of 400 nm. Cladding layer 26 is formed of, for example, p-InP having a thickness of 2 μm. Contact layer 28 is formed of (p+)-gallium indium arsenide (GaInAs) or the like. Active layer 24 includes a plurality of well layers and barrier layers alternately stacked, and has a multi-quantum well (MQW) structure. The well layer and the barrier layer are formed of non-doped gallium indium arsenide phosphide (i-GaInAsP) or the like. A thickness of active layer 24 is, for example, 300 nm. Active layer 24 has an optical gain and emits light having a wavelength of, for example, 1.55 μm. Each layer of semiconductor device 20 may be formed of a III-V compound semiconductor other than the above.

As illustrated in FIG. 1A, semiconductor device 20 has a mesa 30, electrodes 32 and 34. Mesa 30 of semiconductor device 20 is located above waveguide 11. A tip of Mesa 30 has a tapered shape, and is tapered along waveguide 11. Mesa 30 and the tapered tip of semiconductor device 20 are the element structure.

As illustrated in FIG. 1B, mesa 30 is formed of active layer 24, cladding layer 26 and contact layer 28, and is located above waveguide 11. Cladding layer 22 is located between mesa 30 and substrate 10 and extends to the outside of mesa 30. Cladding layer 22 is in contact with a top surface of waveguide 11 and a top surface of terrace 15 of substrate 10. Mesa 30 and a surface of cladding layer 22 are covered by electrically insulating film 18. Electrically insulating film 18 has openings on mesa 30 and on cladding layer 22.

As illustrated in FIG. 1B, electrode 32 extends from a top of mesa 30 to a top surface of electrically insulating film 18 on the outside of mesa 30. Electrode 32 is electrically connected to contact layer 28 through the opening in electrically insulating film 18. Electrode 32 is formed of, for example, a stack of titanium (Ti), platinum (Pt), and gold (Au). Electrode 34 is spaced apart from electrode 32, is disposed on the top surface of electrically insulating film 18 and electrically connected to cladding layer 22 through the opening in electrically insulating film 18. Electrode 34 is formed of metal such as an alloy of gold, germanium, and nickel (AuGeNi). A plating layer of Au or the like may be provided on electrode 32 and electrode 34.

A voltage is applied to electrodes 32 and 34 to inject carriers into active layer 24 of semiconductor device 20. By injecting carriers, active layer 24 generates light. Semiconductor device 20 and substrate 10 are evanescently optically coupled to each other, and the light transmits to waveguide 11 of substrate 10. The light propagates through waveguide 11 and is emitted from an end of substrate 10 to the outside of semiconductor optical device 100.

### (Method of Manufacturing)

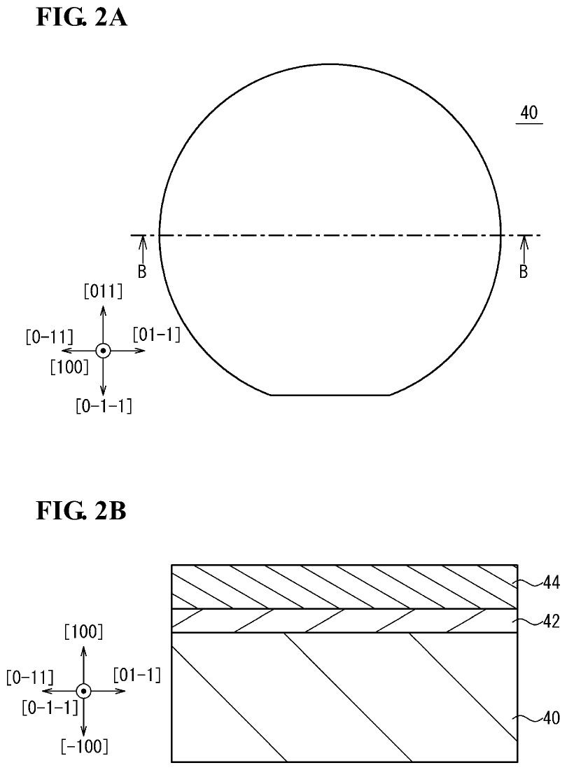

FIGS. 2A to 7B are diagrams each illustrating a method of manufacturing semiconductor optical device 100. FIG. 2A is a plan view illustrating a substrate 40 (second substrate). FIG. 2B is a cross-sectional view taken along line B-B of FIG. 2A. In the drawings, directions of the crystal of substrate 40 are illustrated. In FIG. 2A, a front surface of substrate 40 is a (100) plane. A direction from the back to the front of substrate 40 is a direction. An upward direction is a direction. A downward direction is a [0-1-1] direction. A rightward direction is a [01-1] direction. A leftward direction is a [0-11] direction. The [0-11] direction and the [01-1] direction correspond to a first direction. The direction and the [0-1-1] direction correspond to a second direction, and intersect with the [0-11] direction and the [01-1] direction. The direction and the [0-1-1] direction are orthogonal to the [0-11] direction and the [01-1] direction.

Substrate 40 illustrated in FIG. 2A is, for example, a 2-inch InP substrate. As illustrated in FIG. 2B, an etching stop layer 42 (first semiconductor layer) and a semiconductor layer 44 (second semiconductor layer) are epitaxially grown in this order on one surface of substrate 40 by, for example, metalorganic vapor phase epitaxy (MOVPE) method. Semiconductor layer 44 includes cladding layer 22, active layer 24, cladding layer 26, and contact layer 28 illustrated in FIG. 1B. Cladding layer 22, active layer 24, cladding layer 26, and contact layer 28 are stacked in this order on etching stop layer 42. Substrate 40 is formed of, for example, indium phosphide (InP) having a thickness of 350 μm. Etching stop layer 42 is formed of, for example, indium gallium arsenide (InGaAs) having a thickness of 0.3 μm. After the growth of semiconductor layer 44, substrate 40, etching stop layer 42, and semiconductor layer 44 are cut to form a chip 43.

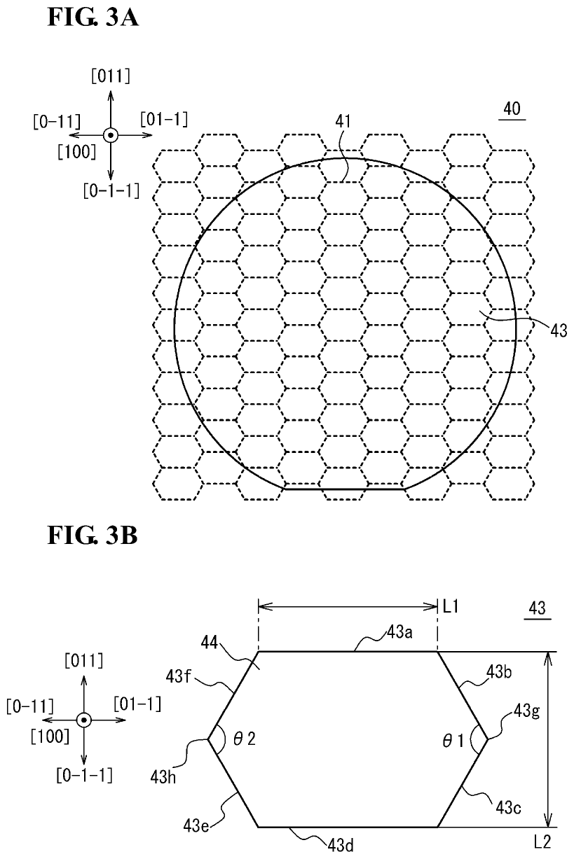

FIG. 3A is a plan view illustrating a cutting process. In FIG. 3A, cutting-plane lines 41 are illustrated by dotted lines. Cutting-plane line 41 is defined so that hexagonal shapes are spread all over on the front surface of substrate 40. A cutting method is, for example, an optical method such as laser ablation. By irradiating the laser light, substrate 40, etching stop layer 42, and semiconductor layer 44 are cut, and chip 43 is formed.

FIG. 3B is a plan view illustrating an enlarged view of one chip 43. Chip 43 has a hexagonal shape in plan view. Chip 43 has six sides 43a, 43b, 43c, 43d, 43e, and 43f. Side 43a and side 43d face each other. Side 43a and side 43d are perpendicular to the direction and the [0-1-1] direction, and are parallel to the [0-11] direction and the [01-1] direction. Lengths L1 of side 43a and side 43d are, for example, 5 mm. Lengths L2 of chip 43 in the direction and the [0-1-1] direction are, for example, 5 mm.

Side 43b, side 43c, side 43e, and side 43f are inclined with respect to the direction, the [0-1-1] direction, the [0-11] direction, and the [01-1] direction, and are not parallel to a (01-1) plane or a (0-11) plane. Side 43b, side 43c, side 43e, and side 43f are not perpendicular to the [0-11] direction or the [01-1] direction. Side 43b and side 43e are parallel to each other. Side 43c and side 43f are parallel to each other. Side 43b and side 43f face each other in the [0-11] direction and the [01-1] direction. Side 43c and side 43e face each other in the [0-11] direction and the [01-1] direction.

Side 43b and side 43c form a vertex 43g. Side 43e and side 43f form a vertex 43h. Vertex 43g and vertex 43h face each other in the [0-11] direction and the [01-1] direction. Vertex 43g protrudes toward the [01-1] direction. Vertex 43h protrudes toward the [0-11] direction. An angle θ1 of vertex 43g and an angle θ2 of vertex 43h are, for example, 60° to 120°. The angle θ1 may be equal to or different from the angle θ2. The inclination angle of each of side 43b, side 43c, side 43e, and side 43f from the direction and the [0-1-1] direction is, for example, 30° to 60°.

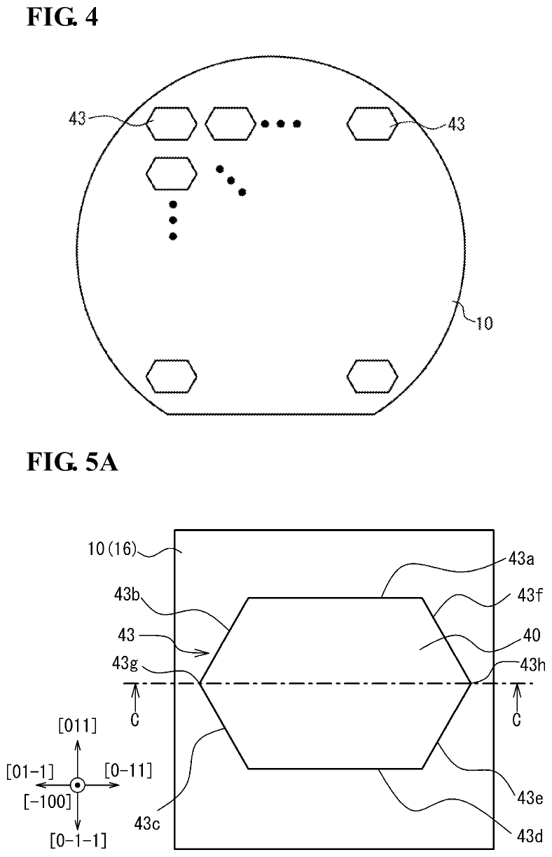

FIG. 4 is a plan view illustrating substrate 10. Substrate 10 is, for example, a wafer having a diameter of 10 inches. As illustrated in FIG. 4, a plurality of chips 43 are bonded to substrate 10. A bonding method is hydrophilic bonding or plasma activated bonding. A surface of semiconductor layer 44 of chip 43 and a surface of Si layer 16 of substrate 10 are hydrophilized or activated by plasma irradiation.

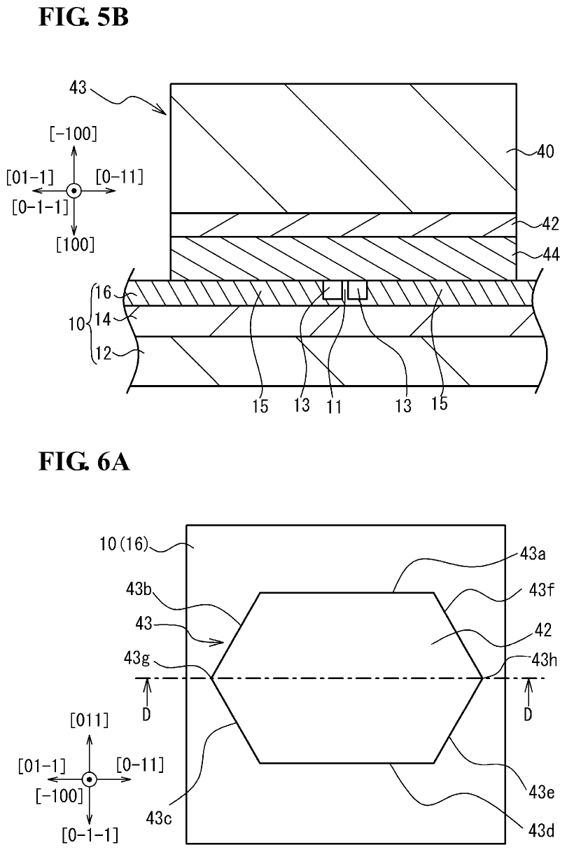

FIGS. 5A, 6A, and 7B are enlarged plan views of one chip 43. FIGS. 5B, 6B and 7B are cross-sectional views along line C-C of the corresponding plan views, respectively.

As illustrated in FIG. 5B, the surface of semiconductor layer 44 is opposed to and brought into contact with the surface of Si layer 16 of substrate 10. After the contact, heat treatment is performed at a temperature of, for example, 300° C. to increase the bonding strength. Substrate 10, semiconductor layer 44, etching stop layer 42, and substrate 40 are sequentially arranged on top of one another in the Z-axis direction. Substrate 40 of chip 43 is located opposite to substrate 10 with semiconductor layer 44 and etching stop layer 42 interposed therebetween. Semiconductor layer 44 is bonded onto waveguide 11 of substrate 10.

After chip 43 is bonded, wet etching is performed from a back surface of substrate 40. When substrate 40 is the InP substrate, the back surface of substrate 40 is a (−100) plane. When substrate 40 is the InP substrate, a solution containing hydrochloric acid (HCl) is used as the etchant. The etchant solution is selected according to the material constituting substrate 40.

When the wet etching is performed on the (−100) plane of the InP substrate using a hydrochloric acid-based etchant, the etching proceeds in the thickness direction of substrate 40, i.e., the direction. The wet etching proceeds in the direction and also proceeds in the plane of substrate 40. That is, the wet etching proceeds three dimensionally in all directions.

The wet etching of substrate 40 has anisotropy. The etching also proceeds in the [01-1] direction, the [0-11] direction, the direction, and the [0-1-1] direction. The ease with which the etching proceeds varies from direction to direction. An etching rate in a direction perpendicular to a plane having an angle of 35 degrees with respect to the (−100) plane is extremely small, and the etching hardly proceeds in this direction. The time from the start of the wet etching of substrate 40 to the time when substrate 40 is dissolved and disappears in a certain direction is defined as the etching rate in the direction. The etching rate in the [01-1] direction and the etching rate in the [0-11] direction are less than the etching rate in the direction and the etching rate in the [0-1-1] direction. That is, the wet etching is less likely to proceed in the [01-1] direction and the [0-11] direction, and is easy to proceed in the direction and the [0-1-1] direction.

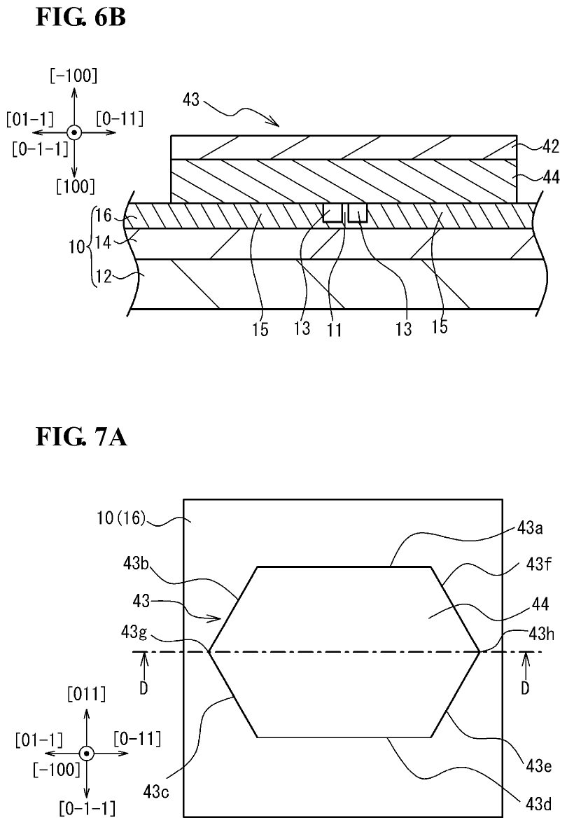

As illustrated in FIG. 5A, chip 43 has a hexagonal shape when viewed in plan view, and does not have sides perpendicular to the [01-1] direction or the [0-11] direction. A surface having a low etching rate is less likely to be exposed. The wet etching proceeds in both the direction and the in-plane direction. The wet etching reaches etching stop layer 42 in the direction and stops at etching stop layer 42. The wet etching reaches side 43a, side 43b, side 43c, side 43d, side 43e, and side 43f of chip 43. As illustrated in FIGS. 6A and 6B, substrate 40 is removed from chip 43 by the wet etching. Etching stop layer 42 is exposed. After the wet etching of substrate 40 is completed, the subsequent steps are performed on chip 43.

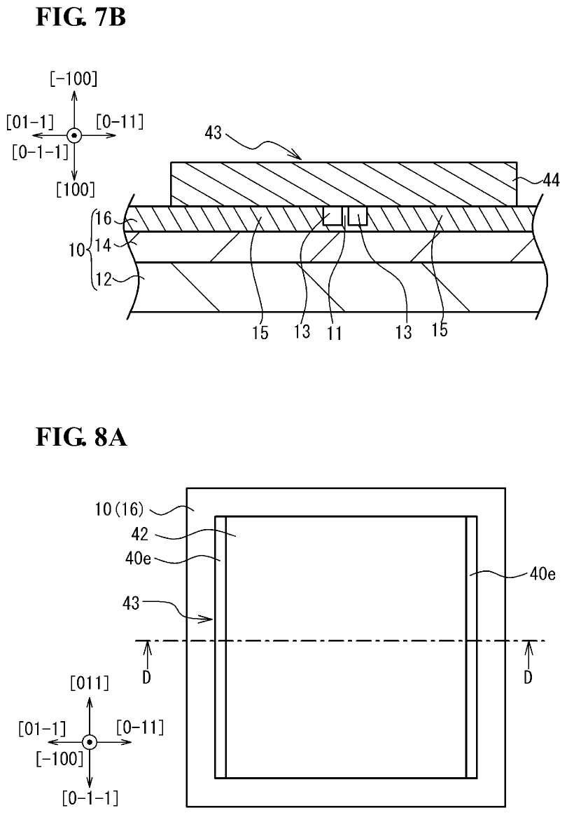

As illustrated in FIGS. 7A and 7B, etching stop layer 42 is removed. Semiconductor layer 44 is exposed. A resist pattern, an etching mask, and the like are provided on or above semiconductor layer 44. Semiconductor layer 44 is etched to form semiconductor device 20 illustrated in FIGS. 1A and 1B from semiconductor layer 44. Semiconductor optical device 100 is formed.

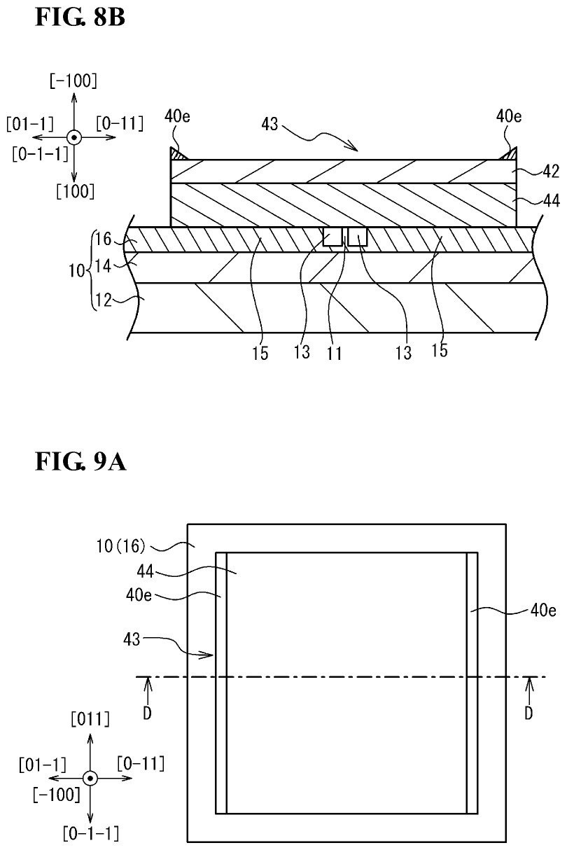

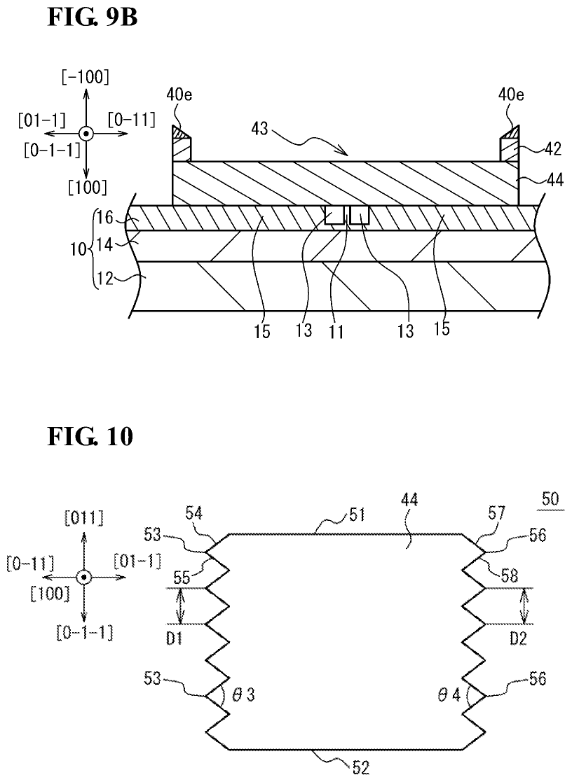

FIGS. 8A and 9A are plan views each illustrating a method of manufacturing a semiconductor optical device according to a comparative example. FIGS. 8B and 9B are cross-sectional views along line D-D of the corresponding plan views, respectively. Chip 43 has a rectangle shape when viewed in plan view. Two sides of chip 43 are perpendicular to the [01-1] direction and the [0-11] direction.

In the wet etching of substrate 40, when the etching proceeds in the [01-1] direction and the [0-11] direction, a specific crystal plane having an angle of 35 degrees with respect to the (−100) plane and extending parallel to the direction is likely to be exposed. The etching rate in the direction perpendicular to the plane inclined at 35 degrees with respect to the (−100) plane is extremely small. When the plane inclined at an angle of 35 degrees is exposed, the etching is less likely to proceed in a direction perpendicular to the plane. Compared to the direction and the [0-1-1] direction, the etching is less likely to proceed in the [01-1] direction and the [0-11] direction.

As illustrated in FIGS. 8A and 8B, in the [01-1] direction and the [0-11] direction, portions of substrate 40 remain unremoved as residues 40e. After the wet etching of substrate 40, wet etching is performed on etching stop layer 42. As illustrated in FIGS. 9A and 9B, residues 40e and underlying etching stop layer 42 remain. Two residues 40e extend along two respective sides. Residue 40e protrudes upward from a top surface of etching stop layer 42. A cross-sectional shape of residue 40e is a triangle. A base angle of residue 40e is, for example, 35 degrees. A height of residue 40e is, for example, 20 μm. A length of the bottom of residue 40e is, for example, 30 μm. Due to the presence of residues 40e, it is difficult to form a resist pattern, an etching mask, and the like on semiconductor layer 44.

According to the first embodiment, after chip 43 is bonded to substrate 10, chip 43 is subjected to wet etching. The wet etching is less likely to proceed in the [01-1] direction and the [0-11] direction, and proceeds more easily in the direction and the [0-1-1] direction. As illustrated in FIG. 3B, chip 43 has a hexagonal shape when viewed in plan view, and does not have sides perpendicular to the [0-11] direction or the [01-1] direction. In the wet etching process, a surface having a low etching rate is less likely to be exposed. The wet etching proceeds in the direction and also proceeds in the plane of substrate 40. The wet etching reaches etching stop layer 42 and the side of chip 43, and thus substrate 40 is removed. As illustrated in FIGS. 6A and 6B, occurrence of residues can be suppressed. Semiconductor device 20 can be formed by processing chip 43 without the residues.

When the side of chip 43 is parallel to the direction and the [0-1-1] direction, that is, parallel to the (01-1) plane and the (0-11) plane, a plane having a low etching rate is exposed in the middle of the wet etching. As illustrated in FIGS. 8A and 8B, the residues are likely to occur. According to the first embodiment, as illustrated in FIG. 3B, chip 43 has a hexagonal shape when viewed in plan view. Side 43b, side 43c, side 43e, and side 43f of chip 43 are inclined from the direction and the [0-1-1] direction, and are not parallel to the (01-1) plane or the (0-11) plane. A surface having a low etching rate is less likely to be exposed, and the wet etching proceeds more easily. Occurrence of the residues can be suppressed.

Side 43b and side 43c form vertex 43g. Side 43e and side 43f form vertex 43h. If the angle θ1 of vertex 43g and the angle θ2 of vertex 43h are too large, side 43b, side 43c, side 43e, and side 43f become close to being parallel to the direction and the [0-1-1] direction, and become close to being perpendicular to the [01-1] direction and the [0-11] direction. The residues may occur. If the angles θ1 and θ2 are too small, substrate 40 may remain in the thickness direction when the wet etching proceeds to the vicinity of the vertex. The angles θ1 and θ2 are, for example, 60° to 120°. Side 43b, side 43c, side 43e, and side 43f become away from limes perpendicular to the [01-1] direction and the [0-11] direction. The wet etching proceeds to the vertex and in the thickness direction to etching stop layer 42. Occurrence of the residues is suppressed. The angles θ1 and θ2 may be, for example, 30° or more, 40° or more, 50° or more, 110° or less, 130° or less, or 140° or less.

Vertex 43g and vertex 43h face each other in the [01-1] direction and the [0-11] direction. Vertex 43g and vertex 43h are located on both sides of chip 43. By proceeding the wet etching to vertex 43g and vertex 43h, occurrence of the residues on both sides of chip 43 can be suppressed.

Side 43b, side 43c, side 43e, and side 43f may have the same length or may have different lengths. The angle θ1 of vertex 43g may be the same as or different from the angle θ2 of vertex 43h. Since side 43b, side 43c, side 43e, and side 43f have the same length and the angle θ1 of vertex 43g is the same as the angle θ2 of vertex 43h, the material of the III-V compound semiconductor can be effectively utilized. As illustrated in FIG. 3A, cutting-plane line 41 is set so that a plurality of hexagonal shapes are spread all over on substrate 40. The adjacent hexagonal shapes are aligned so as to be engaged with each other, and a gap is hardly generated. The portion of substrate 40 that becomes chip 43 increases, and the portion that is discarded decreases. Waste is less likely to occur.

Substrate 40 is cut by using an optical method. The accuracy is improved by using the optical method as compared with the method using a blade. Chip 43 can be formed into a desired shape. The optical method is a method of cutting by irradiating a laser beam.

Since the etching selectivity between substrate 40 and etching stop layer 42 is high, substrate 40 can be removed by wet etching after the bonding. For example, substrate 40 is formed of InP. Etching stop layer 42 is formed of InGaAs. Hydrochloric acid is used as an etchant for wet etching. Substrate 40 can be removed, and the wet etching can be stopped at etching stop layer 42. Substrate 40 may include InP or may be formed of a semiconductor other than InP. Etching stop layer 42 may include InGaAs or may be formed of a semiconductor other than InGaAs. The etchant may contain a solution other than hydrochloric acid.

Since occurrence of residue 40e is suppressed, a resist pattern, etching masks, and the like can be formed on semiconductor layer 44. Etching of Semiconductor layer 44 may be performed to form mesa 30 having a tapered shape as illustrated in FIG. 1A.

The surface of substrate 40 is assumed to be the (100) plane. The plane orientation of the front surface of substrate 40 may be inclined by 15° or less, for example, 2°, 6°, or 15°, with respect to the (100) plane of InP. Even when such substrate 40 is used, the similar effect as that of the first embodiment can be obtained. The first direction and the second direction may deviate from the [01-1] direction and the direction within the range of manufacturing variations. Even when such variations occur, the similar effect can be obtained.

### Second Embodiment

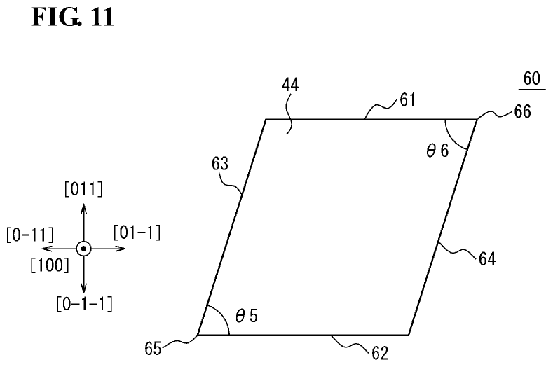

FIG. 10 is a plan view illustrating a method of manufacturing a semiconductor optical device according to a second embodiment, in which one chip is illustrated similarly to FIG. 3B of the first embodiment. The description of the same configurations as those of the first embodiment will be omitted.

As illustrated in FIG. 10, a shape of a chip 50 in plan view in the second embodiment is a polygonal shape. Chip 50 has a side 51 and a side 52. Side 51 and side 52 face each other and are parallel to each other. Side 51 and side 52 are perpendicular to the direction and the [0-1-1] direction, respectively. A side 54, a side 55, a side 57, and a side 58 are inclined from the direction and the [0-1-1] direction, and are not parallel to the (0-11) plane or the (01-1) plane. Side 54, side 55, side 57, and side 58 are not perpendicular to the [0-11] direction or the [01-1] direction.

Chip 50 includes a plurality of vertices 53 and a plurality of vertices 56. The plurality of vertices 53 and the plurality of vertices 56 are aligned between side 51 and side 52. Vertex 53 and vertex 56 face each other. One vertex 53 is formed by side 54 and side 55. Vertex 53 protrudes toward the [0-11] direction. One vertex 56 is formed by side 57 and side 58. Vertex 56 protrudes toward the [01-1] direction. An angle θ3 of vertex 53 and an angle θ4 of vertex 56 are, for example, 60° or more. The angle θ3 may be equal to the angle θ4 or may be different from the angle θ4.

A distance D1 between two adjacent vertices 53 and a distance D2 between two adjacent vertices 56 are, for example, 50 μm to 500 μm. The distance D1 may be equal to the distance D2 or may be different from the distance D2.

After chip 50 is bonded to substrate 10, substrate 40 is removed by wet etching. Substrate 40 is removed from chip 50 by the wet etching. Etching stop layer 42 is exposed. The process after the removal of substrate 40 are the same as that of the first embodiment.

According to the second embodiment, the shape of chip 50 in plan view is a polygonal shape, and does not have sides perpendicular to the [0-11] direction or the [01-1] direction. A surface having a low etching rate is less likely to be exposed during the wet etching. The wet etching proceeds in the direction and also in the in-plane direction. The wet etching reaches etching stop layer 42 in the direction and stops at etching stop layer 42. The wet etching reaches the sides of chip 50. Occurrence of the residues can be suppressed. Semiconductor device 20 can be formed by processing chip 50 without the residues.

Side 54, side 55, side 57, and side 58 of chip 50 are inclined from the direction and the [0-1-1] direction, and are not parallel to the (01-1) plane or the (0-11) plane. A surface having a low etching rate is less likely to be exposed, and the wet etching proceeds more easily. Occurrence of the residues can be suppressed.

Side 54 and side 55 form vertex 53. Side 57 and side 58 form vertex 56. If the angle θ3 of vertex 53 and the angle θ4 of vertex 56 are too large, side 54, side 55, side 57, and side 58 become close to being perpendicular to the [0-11] direction and the [01-1] direction. The residues may occur. If the angles θ3 and θ4 are too small, substrate 40 may remain in the thickness direction when the wet etching proceeds to the vicinity of the vertex. The angles θ3 and θ4 are, for example, 60° to 120°. Side 54, side 55, side 57, and side 58 become away from the lines perpendicular to the [01-1] direction and the [0-11] direction. The wet etching proceeds to the vertex and in the thickness direction to etching stop layer 42. Occurrence of the residues is suppressed. The angles θ3 and θ4 may be, for example, 30° or more, 40° or more, 50° or more, 110° or less, 130° or less, or 140° or less.

A plurality of vertices 53 and a plurality of vertices 56 are aligned in the direction and the [0-1-1] direction. Vertex 53 and vertex 56 face each other in the [01-1] direction and the [0-11] direction. By proceeding the wet etching to the plurality of vertices 53 and the plurality of vertices 56, occurrence of the residues on both sides of chip 50 can be suppressed. In the example of FIG. 10, the number of vertex 53 and the number of vertex 56 are six, respectively. The number of each of vertices 53 and 56 may be six or less, or six or more.

Side 54, side 55, side 57, and side 58 may have the same length. The angle θ3 of vertex 53 and the angle θ4 of vertex 56 may be equal to each other. Cutting-plane line 41 is set so that the vertices are engaged with each other and chips 50 are spread all over. The portion of substrate 40 that becomes chip 50 increases, and the portion that is discarded decreases. Waste is less likely to occur.

### Third Embodiment

FIG. 11 is a plan view illustrating a method of manufacturing a semiconductor optical device according to a third embodiment, in which one chip is illustrated similarly to FIG. 3B of the first embodiment. The description of the same configurations as those of any one of the first embodiment and the second embodiment will be omitted.

As illustrated in FIG. 11, a shape of a chip 60 in plan view in the third embodiment is a parallelogram shape. Chip 60 has a side 61, a side 62, a side 63, and a side 64. Side 61 and side 62 face each other and are parallel to each other. Side 61 and side 62 are perpendicular to the direction and the [0-1-1] direction, respectively.

Side 63 and side 64 face each other and are parallel to each other. Side 63 and side 64 are inclined from the direction and the [0-1-1] direction, and are not parallel to the (0-11) plane or the (01-1) plane. Side 63 and side 64 are not perpendicular to the [0-11] direction or the [01-1] direction. The inclination angle is, for example, 45° or less.

Side 62 and side 63 form a vertex 65. Side 61 and side 64 form a vertex 66. Vertex 65 protrudes toward the [0-11] direction. Vertex 66 protrudes toward the [01-1] direction. Vertex 65 and vertex 66 face each other along the direction of the diagonal line of the parallelogram shape. The angle θ5 of vertex 65 and the angle θ6 of vertex 66 are, for example, 45° or more and less than 90°. The angle θ5 may be equal to the angle θ6 or may be different from the angle θ6.

After chip 60 is bonded to substrate 10, substrate 40 is removed by wet etching. Substrate 40 is removed from chip 60 by the wet etching. Etching stop layer 42 is exposed. The process after the removal of substrate 40 is the same as that of the first embodiment.

According to the third embodiment, the shape of chip 60 in plan view is a parallelogram shape and does not have sides perpendicular to the [0-11] direction or the [01-1] direction. A surface having a low etching rate is less likely to be exposed during the wet etching. The wet etching proceeds in the direction and also in the in-plane direction. The wet etching reaches etching stop layer 42 in the direction and stops at etching stop layer 42. The wet etching reaches the sides of chip 60. Occurrence of the residues can be suppressed. Semiconductor device 20 can be formed by processing chip 60 without the residues.

Side 63 and side 64 of chip 60 are inclined from the direction and the [0-1-1] direction, and are not parallel to the (01-1) plane or the (0-11) plane. A surface having a low etching rate is less likely to be exposed, and the wet etching proceeds more easily. Occurrence of the residues can be suppressed.

Side 61 and side 62 are inclined by 90° from the direction and the [0-1-1] direction. Side 63 and side 64 are inclined from the direction and the [0-1-1] direction. The inclination angle is, for example, 45° or less. Side 62 and side 63 form vertex 65. Side 61 and side 64 form vertex 66. When the angle θ5 of vertex 65 and the angle θ6 of vertex 66 are 90°, side 63 and side 64 are parallel to the direction and the [0-1-1] direction, and are perpendicular to the [01-1] direction and the [0-11] direction. The residues may occur in the wet etching process. If the angles θ5 and θ6 are too small, substrate 40 may remain in the thickness direction when the wet etching proceeds to the vicinity of the vertex. The angles θ5 and θ6 are, for example, 45° or more and less than 90°. Side 63 and side 64 become away from the lines perpendicular to the [01-1] direction and the [0-11] direction. The wet etching proceeds to the vertex and in the thickness direction to etching stop layer 42. Occurrence of the residues is suppressed. The angles θ5 and θ6 may be, for example, 40° or more, 50° or more, 80° or less, or 85° or less.

Side 63 and side 64 may have the same length. Side 61 and side 62 may have the same length. The angle θ5 of vertex 65 may be equal to the angle θ6 of vertex 66. Cutting-plane line 41 is set so that chips 60 are spread all over. The portion of substrate 40 that becomes chip 60 increases, and the portion that is discarded decreases. Waste is less likely to occur.

The shape of the chip in plan view is a polygonal shape, and may be, for example, a hexagonal shape or a parallelogram shape, or may be a shape in which a plurality of vertices are aligned as illustrated in FIG. 10. The shape of the chip in plan view may be, for example, a triangle or a trapezoid, and does not have sides perpendicular to the [0-11] direction or the [01-1] direction. As in the example of FIG. 3A, cutting-plane line 41 is defined so that polygonal shapes are spread all over on substrate 40. The portion of substrate 40 that is discarded decreases. The shape of the chip in plan view may be a shape including a curve, such as a circle and an ellipse.

Although the embodiments of the present disclosure have been described in detail, the present disclosure is not limited to the specific embodiments, and various modifications and changes can be made within the scope of the gist of the present disclosure described in the claims.

What is claimed is:

1. A method of manufacturing a semiconductor optical device including a chip containing a III-V compound semiconductor and a first substrate,
wherein the chip includes a second substrate and a semiconductor layer stacked on the second substrate,
wherein the method comprises:
forming the chip by cutting the second substrate and the semiconductor layer;
bonding the semiconductor layer of the chip to the first substrate; and
removing the second substrate by etching the chip bonded to the first substrate,
wherein a shape of the chip in plan view does not have a side perpendicular to a first direction, and
wherein, in the removing the second substrate, etching proceeds more easily in a second direction crossing the first direction than in the first direction.

2. The method of manufacturing the semiconductor optical device according to claim 1,
wherein the chip has a polygonal shape when viewed in plan view and has a side inclined from a line extending in the second direction.

3. The method of manufacturing the semiconductor optical device according to claim 2,
wherein the side, which is inclined, includes two sides, and the two sides form a vertex, and
wherein the vertex has an angle of 60° to 120°.

4. The method of manufacturing the semiconductor optical device according to claim 2,
wherein the chip has a hexagonal shape when viewed in plan view,
wherein two of six sides of the hexagonal shape form a vertex,
wherein other two of the six sides form another vertex, and
wherein the vertex and the other vertex face each other in the first direction.

5. The method of manufacturing the semiconductor optical device according to claim 3,
wherein a plurality of the vertices are aligned in the second direction, and
wherein at least one of the vertices and at least another one of the vertices face each other in the first direction.

6. The method of manufacturing the semiconductor optical device according to claim 2,
wherein the chip has a parallelogram shape when viewed in plan view.

7. The method of manufacturing the semiconductor optical device according to claim 6,
wherein two vertices of the chip each have an angle of 45° or more and less than 90º.

8. The method of manufacturing the semiconductor optical device according to claim 1,
wherein, in the forming the chip, the second substrate and the semiconductor layer are cut by using an optical method.

9. The method of manufacturing the semiconductor optical device according to claim 1,
wherein the second substrate contains indium phosphide,
wherein the semiconductor layer contains indium gallium arsenide, and
wherein, in the removing the second substrate, the second substrate is removed by wet etching using an etchant containing hydrochloric acid.

10. The method of manufacturing the semiconductor optical device according to claim 1,
wherein the semiconductor layer includes a first semiconductor layer and a second semiconductor layer,
wherein the second substrate, the first semiconductor layer, and the second semiconductor layer are sequentially stacked on top of one another,
wherein, in the bonding, the second semiconductor layer is bonded to the first substrate, and
wherein the manufacturing method further comprises:
removing the first semiconductor layer after the removing the second substrate; and
etching the second semiconductor layer.
